(19) United States
(12) Patent Application Publication
(10) Pub. No.: US 2026/0190265 A1
(43) Pub. Date: Jul. 2, 2026

(54) DISPLAY DEVICE

(71) Applicant: LG Display Co., Ltd., Seoul (KR)

(72) Inventor: Soohyun PARK, Gumi-si (KR)

(73) Assignee: LG Display Co., Ltd., Seoul (KR)

(21) Appl. No.: 19/377,996

(22) Filed: Nov. 3, 2025

(30) Foreign Application Priority Data
Dec. 26, 2024 (KR) 10-2024-0197287

(51) Int. Cl. H05K 5/03; B60K 35/22; G02B 27/01

(52) U.S. Cl. CPC H05K 5/03; B60K 35/22; B60K 2360/68; G02B 27/0101

(57) ABSTRACT

A display device is capable of preventing or minimizing light leakage which can occur due to a structure in which a cover member and a side portion of a display module are exposed to the outside. To this end, the display device can include a display panel having a plurality of sub-pixels, a cover member disposed on top of the display panel, and a side cover member constructed to surround an outer side portion of the cover member. The cover member has four outer side portions. The side cover member is constructed to cover an upper surface, a side surface, and a lower surface of each of the four outer side portions of the cover member. Thus, a path through which light can leak when an image is displayed can be blocked with the side cover member such that the occurrence of light leakage is suppressed.

### CROSS-REFERENCE TO RELATED APPLICATION

This application claims priority to Korean Patent Application No. 10-2024-0197287, filed on December 26, 2024, in the Korean Intellectual Property Office, the entire contents of which are hereby expressly incorporated by reference into the present application.

### BACKGROUND

### Technical Field

The present disclosure relates to a display device, more particularly, for example, without limitation, to a display device configured to prevent light leakage.

### Discussion of the Related Art

In recent years, as the uses of display devices have become more diverse, their thickness has become thinner, and their weight has become lighter, the scope of their use is expanding, and the display devices are used in various fields. Thus, the demand for display devices that provide high-quality images is increasing.

A vehicle display device mounted inside a vehicle to provide an image to a user sitting in the driver's seat or passenger seat has become popular.

The vehicle display device includes a display area (also referred to as an active area or AA) that displays a screen and a non-display area (also referred to as a non-active area or NA) formed along an outer edge of the display area. The non-display area is referred to as a bezel area. When the bezel area is thick, the user's gaze is distracted. When the bezel area is thin, the user's gaze is fixed to the screen of the display area, which can increase immersion.

The description provided in the description of the related art section should not be assumed to be prior art merely because it is mentioned in or associated with the description of the related art section. The description of the related art section can include information that describes one or more aspects of the subject technology, and the description in this section does not limit the disclosure.

### SUMMARY OF THE DISCLOSURE

The inventor has realized that, in related art, in order to implement a narrow bezel, a structure in which a cover member and a side surface of a display module are exposed to the outside is applied to the vehicle display device. However, there can be a problem in that when the screen is displayed, light leakage can occur due to the structure in which the cover member and the side portion of the display module are exposed to the outside.

In addition, the display image is reflected on the windshield such that the view of the vehicle driver can be obstructed.

Accordingly, in order to solve or address the above-described problems and other limitations associated with the related art, the inventor of the present disclosure has invented an improved display device capable of preventing or minimizing a light leakage phenomenon from occurring due to a structure in which the cover member and the side portion of the display module are exposed to the outside.

A technical purpose according to an example embodiment of the present disclosure is to provide a display device in which an outer side portion of the cover member is covered with a side cover member to prevent or minimize the light leakage even when the cover member and the side portion of the display module is exposed to the outside.

Purposes according to the present disclosure are not limited to the above-mentioned purposes. Other purposes and advantages according to the present disclosure that are not mentioned can be understood based on following descriptions, and can be more clearly understood based on example embodiments according to the present disclosure. Further, it will be easily understood that the purposes and advantages according to the present disclosure can be realized using means shown in the claims or combinations thereof.

One aspect of the present disclosure provides a display device comprising: a display panel including a plurality of sub-pixels; a cover member disposed on top of the display panel; and a side cover member constructed to surround an outer side portion of the cover member, wherein the cover member has four outer side portions, wherein the side cover member is constructed to cover an upper surface, a side surface, and a lower surface of each of the four outer side portions of the cover member.

In accordance with some example embodiments, the side cover member has a 'U'-shaped cross section, and the outer side portion of the cover member is inserted into a space defined by the U-shaped side cover member.

In accordance with some example embodiments, the display device further comprises: an optical control layer disposed on an upper surface of the display panel; an optical adhesive layer disposed on an upper surface of the optical control layer; the cover member disposed on an upper surface of the optical adhesive layer; and a rear cover having a side portion disposed outwardly of and spaced form the four outer side portions of the cover member.

In accordance with some example embodiments, the optical adhesive layer includes a first optical adhesive layer and a second optical adhesive layer, and a light control film is disposed between the first optical adhesive layer and the second optical adhesive layer.

In accordance with some example embodiments, the side cover member is positioned between the four outer side portions of the cover member and the side portion of the rear cover.

In accordance with some example embodiments, the side cover member extends on along the upper surface, the side surface, and the lower surface of each of the four outer side portions of the cover member, wherein the side cover member faces the upper surface, the side surface, and the lower surface of each of the four outer side portions of the cover member.

In accordance with some example embodiments, the side cover member is coupled and fixed to the cover member through an adhesive.

In accordance with some example embodiments, the side cover member is fixedly combined with the cover member by inserting and fitting the four outer side portions of the cover member into the side cover member.

In accordance with some example embodiments, the side cover member has a U-shaped cross-section having an opening defined therein, wherein each of the four outer side portions of the cover member is closely-fitted into the opening.

In accordance with some example embodiments, the side cover member is inserted between an outermost portion of the rear cover and the cover member, and the four outer side portions of the cover member is surrounded by the side cover member.

In accordance with some example embodiments, the display panel is disposed on a dashboard of a vehicle, and includes a display area in which the plurality of sub-pixels are disposed and a non-display area surrounding the display area.

In accordance with some example embodiments, the rear cover has a flat bottom portion in the display area and the non-display area, wherein a side portion of the rear cover extends upwardly from the bottom portion at an end of the non-display area, wherein the side portion of the rear cover has an upper end spaced apart from the four outer side portions of the cover member by a predetermined spacing.

In accordance with some example embodiments, the display device further comprises: a back plate disposed under the display panel; a metal plate disposed under the back plate; an adhesive tape disposed under the metal plate; and a guide holder disposed under the adhesive tape, wherein a bottom portion of the rear cover is disposed under the guide holder, wherein the guide holder is coupled to and fixed to the rear cover through a fastening means including a screw.

In accordance with some example embodiments, the guide holder receives a source PCB therein, wherein the source PCB is electrically connected to the display panel through a flexible printed circuit board.

In accordance with some example embodiments, the flexible printed circuit board extends from a rear surface of the guide holder to a front surface of the display panel.

In accordance with some example embodiments, a black matrix is disposed on top of the optical adhesive layer, wherein the cover member is disposed on an upper surface of the black matrix.

In accordance with some example embodiments, the black matrix has a plurality of holes defined therein, wherein black pigments fill the plurality of holes.

According to an example embodiment of the present disclosure, the side cover member is disposed on the side portion of the display module, thereby blocking a path through which light leaks when the image is displayed, thereby preventing or minimizing the occurrence of the light leakage phenomenon.

In addition, according to an example embodiment of the present disclosure, the cover member and the side portion of the display module are exposed to the outside, thereby implementing a narrow bezel while preventing or minimizing the light leakage.

In addition, according to an example embodiment of the present disclosure, the outer side portion of the cover member is covered with the side cover member, such that direct external damage to the cover member and the display module can be avoided, and acceptance criteria for visual defects can be applied.

In addition, according to an example embodiment of the present disclosure, the occurrence of the light leakage phenomenon can be prevented such that the display image is not reflected on the windshield, and thus there is an effect of not obstructing the view of the driver of the vehicle.

In addition, according to an example embodiment of the present disclosure, the occurrence of light leakage of the display panel can be prevented to remove the defects of the panel, thereby preventing or minimizing deterioration of the lifespan of the panel.

In addition, according to an example embodiment of the present disclosure, the panel defect can be suppressed such that the display panel can operate without failure, thereby providing a long-life low-power display device.

The effects of the present disclosure are not limited to the above-mentioned effects, and other effects not mentioned can be clearly understood by those skilled in the art from the following descriptions.

In addition to the above-described effects, the specific effects of the present disclosure will be described together while describing specific matters for implementing the example embodiments of the present disclosure below.

### BRIEF DESCRIPTION OF THE DRAWINGS

The accompanying drawings, which are included to provide a further understanding of the disclosure and are incorporated in and constitute a part of this application, illustrate example embodiments of the disclosure and together with the description serve to explain the principle of the disclosure. In the drawings:

FIG. 1 is a diagram schematically illustrating a vehicle on which a display device according to an example embodiment of the present disclosure is mounted.

FIG. 2 is a diagram schematically illustrating an outer appearance of a display device according to an example embodiment of the present disclosure.

FIG. 3 is an exploded perspective view illustrating an example of a display device according to an example embodiment of the present disclosure.

FIG. 4 is an exploded perspective view illustrating a display panel according to an example embodiment of the present disclosure.

FIG. 5 is a diagram illustrating a display module and a rear cover corresponding thereto according to an example embodiment of the present disclosure.

FIG. 6 is a diagram illustrating a cutting line along which a display panel is cut according to an example embodiment of the present disclosure.

FIG. 7 is a cross-sectional view of a display module taken along a line A-A' of FIG. 8 according to an example embodiment of the present disclosure.

FIG. 8 is a diagram illustrating a detailed configuration example of a display module according to an example embodiment of the present disclosure.

FIG. 9 is a cross-sectional view of a display module taken along a line B-B' of FIG. 8 according to an example embodiment of the present disclosure.

FIG. 10 is a detailed configuration diagram illustrating a portion C of FIG. 9 in a display module according to an example embodiment of the present disclosure.

FIG. 11 is a diagram illustrating a coupling state between a side cover member and a cover member according to a first example embodiment of the present disclosure.

FIG. 12 is a diagram illustrating a coupling state between a side cover member and a cover member according to a second example embodiment of the present disclosure.

FIG. 13 is a diagram schematically illustrating a configuration example of a display module to which a side cover member is applied according to an example embodiment of the present disclosure.

FIG. 14 is a diagram schematically illustrating an outer appearance of a side cover member according to an example embodiment of the present disclosure.

FIG. 15 is a cross-sectional view illustrating a cross-section taken along a line D-D' of FIG. 14 of a side cover member according to an example embodiment of the present disclosure.

Throughout the drawings and the detailed description, unless otherwise described, the same drawing reference numerals should be understood to refer to the same elements, features, and structures. The relative size and depiction of these elements can be exaggerated for clarity, illustration, and convenience.

### DETAILED DESCRIPTION OF THE EMBODIMENTS

Advantages and Advantages and features of the present disclosure, and a method of achieving the advantages and features will become apparent with reference to embodiments described later in detail together with the accompanying drawings. However, the present disclosure is not limited to the embodiments as disclosed under, but can be implemented in various different forms. Thus, these embodiments are set forth only to make the present disclosure complete, and to completely inform the scope of the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure can be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as can be included within the spirit and scope of the present disclosure as defined by the appended claims.

The shapes, sizes, dimensions (e.g., length, width, height, thickness, radius, diameter, area, etc.), ratios, angles, numbers, etc. disclosed in the drawings for illustrating embodiments of the present disclosure are illustrative, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The terminology used herein is directed to the purpose of describing particular embodiments only and is not intended to be limiting of the present disclosure. As used herein, the singular constitutes "a" and "an" are intended to include the plural constitutes as well, unless the context clearly indicates otherwise. It will be further understood that the terms such as “include,” “have,” “comprise,” “contain,” “constitute,” “make up of,” “formed of,” and “consist of” when used in this disclosure, specify the presence of the stated features, integers, operations, elements, and/or components, but do not preclude the presence or addition of one or more other features, integers, operations, elements, components, and/or portions thereof. As used herein, the term "and/or" includes any and all combinations of one or more of associated listed items. Expression such as "at least one of" when preceding a list of elements can modify the entire list of elements and may not modify the individual elements of the list. In interpretation of numerical values, an error or tolerance therein can occur even when there is no explicit description thereof.

In describing various embodiments of the present disclosure, in the case of describing a positional relationship, for example, “on”, “above”, “over”, “below”, “under”, “beside”, “beneath”, “near”, “close to,” “adjacent to”, “on a side of”, “next” etc., when the positional relationship of two parts is described, one or more other parts can be located between the two parts unless “immediately” or “directly” is used.

In addition, it will also be understood that when a first element or layer is referred to as being present "on" a second element or layer, the first element can be disposed directly on the second element or can be disposed indirectly on the second element with a third element or layer being disposed between the first and second elements or layers. It will be understood that when an element or layer is referred to as being "connected to", or "coupled to" another element or layer, it can be directly connected to, or coupled to the other element or layer, or one or more intervening elements or layers can be present therebetween. In addition, it will also be understood that when an element or layer is referred to as being "between" two elements or layers, it can be the only element or layer between the two elements or layers, or one or more intervening elements or layers can also be present.

Spatially relative terms, such as “under,” “below,” “beneath”, “lower,” “over,” “upper” and the like, can be used herein for ease of description to describe one element or feature's relationship to another element(s) or feature(s) as illustrated in the figures. It will be understood that the spatially relative terms can encompass different orientations of an element in use or operation in addition to the orientation depicted in the figures. For example, if an element in the figures is inverted, elements described as “below” or “beneath” other elements or features would then be oriented “over” the other elements or features. Thus, the exemplary term “below” can encompass both an orientation of below and above. Similarly, the exemplary term “above” or “over” can encompass both an orientation of “above” and “below”.

Further, as used herein, when a layer, film, area, plate, or the like is disposed "on" or "on top" of another layer, film, area, plate, or the like, the former can directly contact the latter or still another layer, film, area, plate, or the like can be disposed between the former and the latter. As used herein, when a layer, film, area, plate, or the like is directly disposed "on" or "on top" of another layer, film, area, plate, or the like, the former directly contacts the latter and still another layer, film, area, plate, or the like is not disposed between the former and the latter. Further, as used herein, when a layer, film, area, plate, or the like is disposed "beneath" or “under” another layer, film, area, plate, or the like, the former can directly contact the latter or still another layer, film, area, plate, or the like can be disposed between the former and the latter. As used herein, when a layer, film, area, plate, or the like is directly disposed "beneath" or "under" another layer, film, area, plate, or the like, the former directly contacts the latter and still another layer, film, area, plate, or the like is not disposed between the former and the latter.

In descriptions of temporal relationships, for example, temporal precedent relationships between two events such as “after”, “subsequent to”, “before”, etc., another event can occur therebetween unless “directly after”, “directly subsequent” or “directly before” is not indicated.

When a certain embodiment can be implemented differently, a function or an operation specified in a specific block can occur in a different order from an order specified in a flowchart. For example, two blocks in succession can be actually performed substantially concurrently, or the two blocks can be performed in a reverse order depending on a function or operation involved.

It will be understood that, although the terms such as "first", "second", "third", and so on can be used herein to describe various elements, components, areas, layers and/or periods, these elements, components, areas, layers and/or periods should not be limited by these terms. These terms are used to distinguish one element, component, area, layer or section from another element, component, area, layer or period. Thus, a first element, component, area, layer or section as described under could be termed a second element, component, area, layer or period, without departing from the spirit and scope of the present disclosure.

When an embodiment of the present disclosure can be implemented differently, functions or operations specified within a specific block can be performed in a different order from an order specified in a flowchart. For example, two consecutive blocks can actually be performed substantially simultaneously, or the blocks can be performed in a reverse order depending on related functions or operations.

The word “exemplary” is used to mean serving as an example or illustration. Aspects are example aspects. Further, the terms such as “embodiments,” “examples,” “aspects,” and the like should not be construed as preferred or advantageous over other implementations. An embodiment, an example, an exemplary embodiment, an aspect, or the like can refer to one or more embodiments, one or more examples, one or more example embodiments, one or more aspects, or the like, unless stated otherwise. Further, the term “may” encompasses all the meanings of the term “can”.

The features of the various embodiments of the present disclosure can be partially or entirely combined with each other, and can be technically associated with each other or operate with each other. The embodiments can be implemented independently of each other and can be implemented together in an association relationship.

In interpreting a numerical value, the value is interpreted as including an error range unless there is no separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, the terms such as “embodiments,” “examples,” “aspects, and the like should not be construed such that any aspect or design as described is superior to or advantageous over other aspects or designs.

Further, the term 'or' means 'inclusive or' rather than 'exclusive or'. That is, unless otherwise stated or clear from the context, the expression that 'x uses a or b' means any one of natural inclusive permutations.

The terms used in the description below have been selected as being general and universal in the related technical field. However, there can be other terms than the terms depending on the development and/or change of technology, convention, preference of technicians, etc. Therefore, the terms used in the description below should not be understood as limiting technical ideas, but should be understood as examples of the terms for illustrating embodiments.

Further, in a specific case, a term can be arbitrarily selected by the applicant, and in this case, the detailed meaning thereof will be described in a corresponding description period. Therefore, the terms used in the description below should be understood based on not simply the name of the terms, but the meaning of the terms and the contents throughout the Detailed Descriptions.

In description of flow of a signal, for example, when a signal is delivered from a node A to a node B, this can include a case where the signal is transferred from the node A to the node B through another node unless a phrase 'immediately transferred' or 'directly transferred' is used.

Throughout the present disclosure, "A and/or B" means A, B, or A and B, unless otherwise specified, and "C to D" means C inclusive to D inclusive unless otherwise specified.

“At least one” should be understood to include any combination of one or more of listed components. For example, at least one of first, second, and third components means not only a first, second, or third component, but also all combinations of two or more of the first, second, and third components.

As used herein, the term "display device" can include, in a narrow sense, a display device including a liquid crystal module (LCM), an organic light-emitting diode (OLED) module, or a quantum dot (QD) module including a display panel and a driver for driving the display panel. Moreover, the display device can include, in a broad sense, a laptop computer, a television, a computer monitor, an automotive device or an equipment display for a vehicle, a set electronic device, a set device or a set device including a complete product or a final product including the LCM, the OLED module, or the QD module.

Therefore, the display device in accordance with the present disclosure can include, in the narrow sense, a display device itself including, for example, the LCM, the OLED module, QD module, etc., and can include, in a broad sense, the set device as an application product or an end-user device including a complete product or a final product including the LCM, the OLED module, or the QD module.

Moreover, in some cases, the LCM, OLED module, or QD module composed of the display panel and the driver can be expressed as "display device" in a narrow sense. The electronic device as a complete product including the LCM, OLED module or QD module can be expressed as "set" device" in a broad sense. For example, the display device in the narrow sense can include a display panel such as a liquid crystal panel, an organic light-emitting display panel, or a quantum dot display panel, and a source PCB as a controller for driving the display panel. The set device in the broad sense can include a display panel such as a liquid crystal panel, an organic light-emitting display panel, or a quantum dot display panel, a source PCB as a controller for driving the display panel, and a set PCB as a set controller that is electrically connected to the source PCB and controls the set device.

As used herein, the display panel can be of any type of the display panels such as a liquid crystal display panel, an organic light emitting diode (OLED) display panel, a quantum dot (QD) display panel, and an electroluminescent display panel, etc. The display panel used in the disclosure may not be limited to a specific display panel including a flexible substrate for the OLED display panel and an underlying back plate support structure and having a bendable bezel. Moreover, the display panel used in the display device according to an embodiment of the present disclosure is not limited to a shape or a size of the display panel.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein.

In the aspects of the present disclosure, a source electrode and a drain electrode are distinguished from each other, for convenience of description. However, the source electrode and the drain electrode are used interchangeably. The source electrode can be the drain electrode, and the drain electrode can be the source electrode. Also, the source electrode in any one aspect of the present disclosure can be the drain electrode in another aspect of the present disclosure, and the drain electrode in any one aspect of the present disclosure can be the source electrode in another aspect of the present disclosure.

Hereinafter, embodiments of the present disclosure will be described using the attached drawings. A scale of each of components as shown in the drawings is different from an actual scale thereof for convenience of illustration, and therefore, the present disclosure is not limited to the scale as shown in the drawings.

As used herein, a first direction, a second direction, and a third direction, or an X-axis direction, a Y-axis direction, and a Z-axis direction should not be interpreted only as having a geometric relationship with each other in which the first direction, the second direction, and the third direction are perpendicular to each other or the X-axis direction, the Y-axis direction, and the Z-axis direction are perpendicular to each other, but can be interpreted as having a geometric relationship with each other in which the first direction, the second direction, and the third direction interest each other at an angle other than 90 degrees (°) or the X-axis direction, the Y-axis direction, and the Z-axis direction are interest each other at an angle other than 90 degrees (°) within a range in which a configuration of the present disclosure can work functionally.

Hereinafter, a display device according to one or more example embodiments of the present disclosure will be described with reference to the drawings. More specifically, a display device that prevents a displayed image output from the display device from being reflected from a windshield to a viewer will be described with reference to the drawings. All the components of each display device/apparatus and each vehicle according to all embodiments of the present disclosure are operatively coupled and configured.

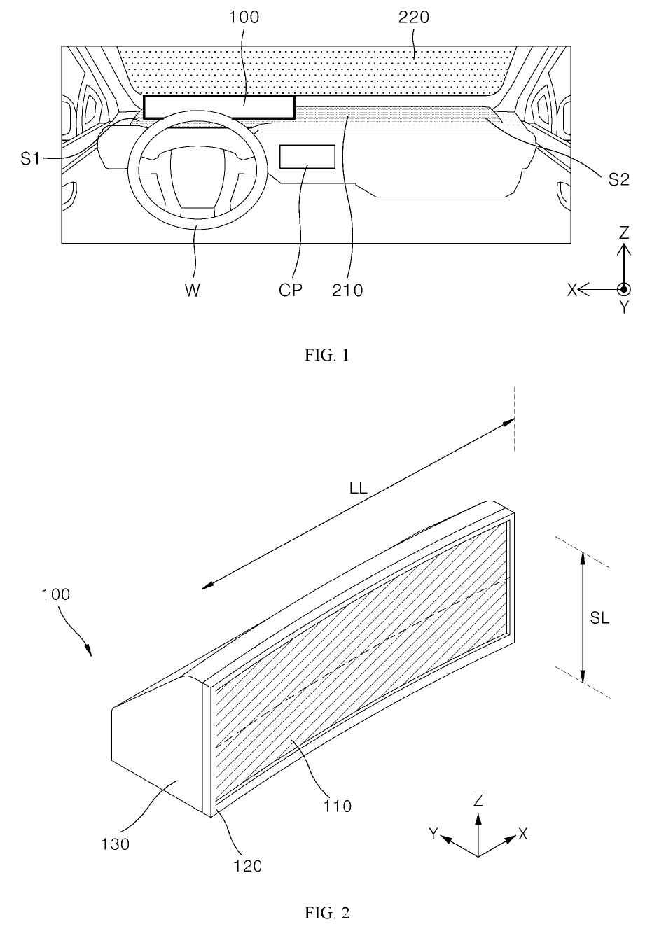

FIG. 1 is a diagram schematically showing a vehicle on which a display device according to an example embodiment of the present disclosure is mounted.

A frontward and upward direction defined in the present disclosure refers to a Z-axis direction, and a backward and downward direction refers to a -Z-axis direction.

Referring to FIG. 1, a vehicle on which a display device according to some example embodiments of the present disclosure is mounted includes a dashboard 210 adjacent to a bottom of a front glass 220 (or a windshield) and a display device 100 disposed on the dashboard 210.

The display device 100 can be disposed between one edge S1 and the other edge S2 of the dashboard 210. FIG. 1 illustrates that the display device 100 is disposed between a steering wheel W and the front glass 220. However, example embodiments of the present disclosure are not limited thereto. Furthermore, the display device 100 can extend from one edge S1 to the other edge S2 of the dashboard 210. In this case, not only the driver but also the passenger in the passenger seat can view the image displayed on the display device 100.

The display device 100 can display an image in a general image mode and a multi-view mode.

The display device 100 displays one image the general image mode as a general display device does. In this case, the display device 100 can display one image in a wide viewing angle range so that all viewers located in front of the display device 100 can comfortably view the image. Thus, both the driver and the passenger in the passenger seat can view one image displayed on the display device 100.

The display device 100 can display a first image in a first direction and a second image in a second direction different from the first direction in the multi-view mode. The first direction can be a direction toward a position on top of the driver's gaze and can be a direction toward a position in front of and on top of the display device 100. The second direction can be the driver's gaze direction and can be a direction toward a position in front of and under the display device 100.

The front glass 220 is present in the first direction. Thus, the first image is directed to the front glass 220 and is thus displayed to the driver as a virtual image. Thus, a head up display (HUD) is realized. Furthermore, the driver is present in the second direction. Thus, the second image is visible to the driver in a real manner, that is, directly.

As discussed above, according to an example embodiment of the present disclosure, the display device 100 that displays the first image in the first direction toward the front windshield 200 and displays the second image in the second direction toward the driver in the multi-view mode is disposed on the dashboard 210 of the vehicle. As a result, according to an example embodiment of the present disclosure, the driver can obtain driving information from a plurality of images because the driver can view the first image in the head-up display manner and at the same time, can directly view the second image. This can increase the driver's driving convenience.

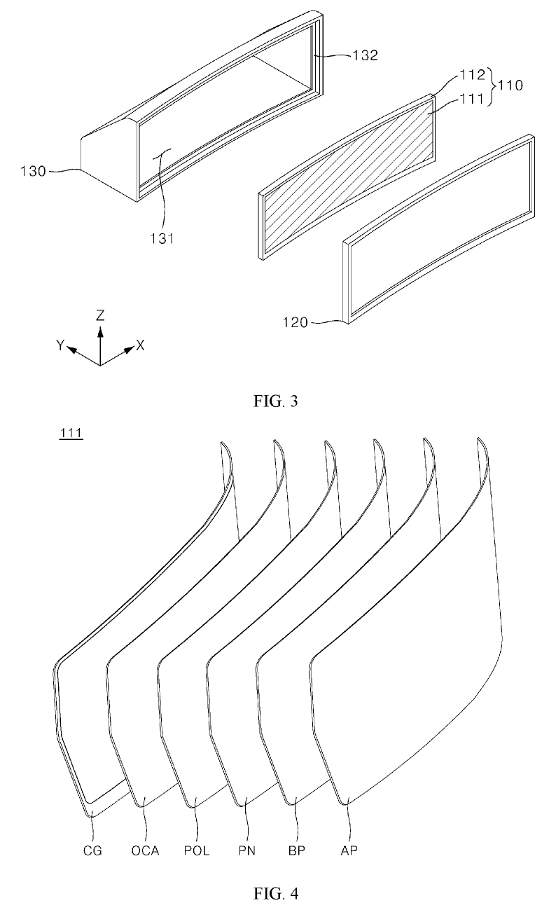

FIG. 2 is a drawing schematically showing an outer appearance of a vehicle display device according to an example embodiment of the present disclosure, and FIG. 3 is an exploded perspective view showing the vehicle display device according to an example embodiment of the present disclosure.

Referring to FIG. 2 and FIG. 3, the display device 100 according to an example embodiment of the present disclosure can have a long side and a short side.

A short side length SL of the display device 100 can be smaller than a short side length of the dashboard 210. A long side length LL of the display device 100 can be smaller than a length from one edge S1 to the other edge S2 of the dashboard 210, as shown in FIG. 1.

The display device 100 according to an example embodiment of the present disclosure can include a display module 110, a front cover 120, and a housing 130.

The display module 110 can include a display panel 111 and a rear cover 112. The display panel 111 can be mounted on the rear cover 112. The display panel 111 can have a front cover 120 as a front portion, and a rear cover 112 as a rear portion.

The display module 110 can be a liquid crystal display module or an organic light-emitting display module. The display module 110 directly displays an image using a liquid crystal display panel or an organic light-emitting display panel. Thus, the display module 110 has excellent outdoor visibility, viewing angle, resolution, and luminance, compared to an image projection scheme, and thus has high information transmission ability, and minimized change in visibility depending on the external environment (weather, or when wipers move).

The display module 110 can include the display panel 111, a guide frame supporting the display panel 111, a lower cover that stores therein a backlight unit and supports the guide frame, and an upper case covering a front edge of the display panel 111 and a side surface of the lower cover. When the display module 110 is embodied as the liquid crystal display module, the display module can further include the backlight unit disposed on a lower surface of the display panel 111 so as to emit light thereto.

The display panel 111 can include one or more display areas. For example, the display panel 111 can include a first display area adjacent to the driver's seat, a second display area facing a separation area between the driver's seat and the passenger seat, and a third display area adjacent to the passenger seat.

The first display area can display at least one of measuring instrument data, around view data, and navigation data that are essential to the driver for safe vehicle driving. In particular, when the vehicle starts driving, the first display area can display the measuring instrument data.

The second display area can display any one of around view data, navigation data, and media data.

The third display area can display around view data, navigation data, and media data. In this regard, the media data corresponds to contents for the entertainment of the user riding on the passenger seat. For example, when the first display area displays the measuring instrument data, the third display area can display the media data.

Both opposing edges of the display panel 111 are bent backwards. In this regard, a reinforcing member that reinforces the bending of the display panel 111 can be disposed on an outside of the display panel 111. In this regard, the reinforcing member can include, for example, a micro coating layer. The micro coating layer can be referred to MCL.

A polarizing layer (POL in FIG. 6) which will be described later can be attached to an upper surface of the display panel 111. The polarizing layer POL can have a transmission axis parallel to the long side of the display panel 111.

The display module 110 is stored in a storage space 131 of the housing 130 and displays an image based on image data supplied from a host system. The host system can supply the image data from at least one of a vehicle external camera, a driving image recording device, a navigation device, a portable terminal, an audio device, and a vehicle driving recording device to the display module 110.

The front cover 120 can be provided in a form of a rectangular ring and can cover a front edge and a side portion of the display module 110.

The housing 130 can accommodate therein the display module 110. The housing 130 can be formed in a box shape having the storage space 131 and having an open front surface facing the driver's seat. A step-shaped module support surface 132 can be formed in a front edge of the storage space 131.

In an example embodiment of the present disclosure, an example in which the display device 100 is mounted on the dashboard 210 of the vehicle is described above. However, example embodiments of the present disclosure are not limited thereto. The display device 100 can be mounted at another location inside the vehicle.

In another example, the display panel 111 can also be disposed on the steering wheel W facing the driver's seat. In this case, the display panel 111 disposed on the dashboard 210 can be referred to as a first display panel unit, and the display panel 111 disposed on the steering wheel W can be referred to as a second display panel unit. In this regard, the second display panel unit can include one or more display areas. When the first display panel unit includes the first to third display areas, the second display panel unit can include a fourth display area.

Furthermore, since the second display panel unit faces the driver's seat, the user riding on the driver's seat can view the second display panel unit without moving his or her eyes to the left or right. Accordingly, like the first display area of the first display panel unit, the fourth display area of the second display panel unit can display at least one of the measuring instrument data, the around view data, and the navigation data that are essential to the driver for safe vehicle driving.

In this regard, the media data corresponds to contents for the user's enjoyment. The around view data corresponds to imaging data obtained from at least one of a rear camera, a front camera, and a side camera. The navigation data corresponds to data from a driving system (or GPS system). The measuring instrument data includes various observed or predicted information about various conditions of the vehicle. For example, the measuring instrument data can include at least one piece of information among the remaining amount of energy source of the vehicle, the vehicle's driving speed, coolant temperature, remaining engine oil amount, engine abnormality, whether a brake is activated, whether warning lights are activated, whether seat belts are worn, cumulative driving distance, possible driving distance, and fuel efficiency.

In another example, the display device 100 according to an example embodiment of the present disclosure can be disposed on a center fascia CP located under the dashboard 210 and between the driver's seat and the passenger seat. In this case, the display panel 111 disposed on the center fascia CP can be referred to as a third display panel unit. Accordingly, when the first display panel unit includes the first to third display areas, and the second display panel unit includes the fourth display area, the third display panel unit can include a fifth display area.

The fifth display area disposed on the center fascia CP can display a control setting window that provides a user control interface for setting surrounding environment data or vehicle status. In this regard, the user control interface can include a user interface for controlling the image data displayed on the first and second display panel units, and a user interface for displaying or controlling the air conditioning status inside the vehicle. The surrounding environment data includes various information about the vehicle. By way of example, the surrounding environment data can include at least one piece of information among the illuminance outside the vehicle, the illuminance inside the vehicle, whether the user is riding on the driver's seat of the vehicle, whether the user is riding on the passenger seat of the vehicle, whether user input is performed using the control setting window, whether a physical shock to the vehicle has occurred, autonomous driving status, the vehicle's driving direction, and the vehicle's driving speed.

However, this is only an example, and it is obvious that the display device 100 mounted on the vehicle can include at least one display panel unit disposed at various locations inside the vehicle. That is, at least one display panel unit of the display device 100 can further include a display panel unit disposed on the windshield, a display panel unit facing the rear seat, etc. in addition to the first, second, and third display panel units. Alternatively, at least one display panel unit of the display device 100 can include only the first display panel unit, or can include the first display panel unit and display panel units respectively disposed at various locations inside the vehicle.

In the display device 100 according to an example embodiment of the present disclosure, at least one display panel unit can provide a plurality of display areas. The plurality of display areas can include the first to third display areas disposed on the dashboard 210 of the vehicle, the fourth display area disposed on the steering wheel W of the vehicle, and the fifth display area disposed on the center fascia CP located under the dashboard 210. The fourth display area can display the measuring instrument data or the around view data, and the fifth display area can display the control setting window that provides the user control interface for setting the status of the vehicle.

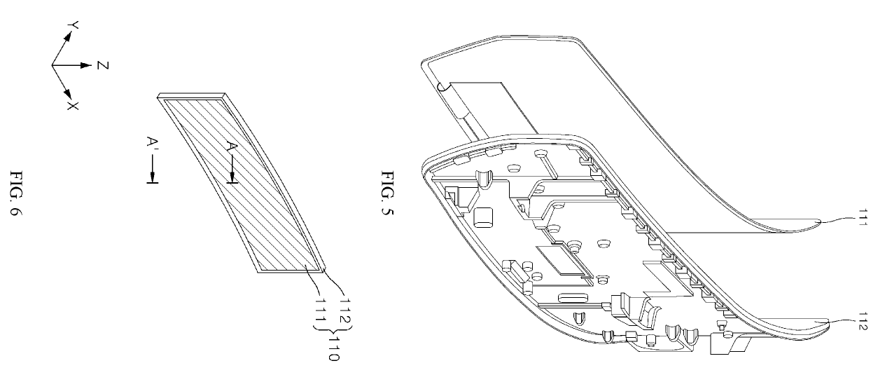

FIG. 4 is an exploded perspective view illustrating a display panel according to an example embodiment of the present disclosure. FIG. 5 is a diagram illustrating a display panel and a rear cover corresponding thereto according to an example embodiment of the present disclosure.

Referring to FIG. 4, the display panel 111 according to an example embodiment of the present disclosure can include a metal plate AP, a back plate BP, a panel array PN, an optical control layer, an optical adhesive layer OCA, and a cover member CG.

The back plate BP and the metal plate AP can support the display panel array PN. The back plate BP and the metal plate AP can be adhered to each other through a resin or an adhesive tape. For example, the back plate BP and the metal plate AP can be bonded to each other using an ultraviolet (UV) curable acrylic resin. However, example embodiments of the present disclosure are not limited thereto. Specifically, a resin disposed between the back plate BP and the metal plate AP can be embodied as a cured product of a resin obtained by performing a curing process of the curable resin. When the resin is used as an ultraviolet-curable resin, ultraviolet curing can be performed. The metal plate AP can be made of a metal material, for example, can be made of an aluminum (Aluminum) material.

The panel array PN can include a plurality of pixels. Each of the plurality of pixels can be composed of a plurality of sub-pixels. For example, Each of the plurality of pixels P can be composed of a red (R) sub-pixel, a green (G) sub-pixel, and a blue (B) sub-pixel, or composed of a red (R) sub-pixel, a green (G) sub-pixel, a blue (B) sub-pixel, and a white (W) sub-pixel. However, the present disclosure is not limited thereto. A plurality of subpixels SP constituting unit pixel can be variously modified in colors and configurations, as necessary.

For example, each of the plurality of subpixels SP can emit light having different wavelengths from each other. For example, the plurality of subpixels SP can include red, green, and blue subpixels, in which the red, green, and blue subpixels can be disposed in a repeated manner. Alternatively, the plurality of subpixels SP can include red, green, blue, and white subpixels, in which the red, green, blue, and white subpixels can be disposed in a repeated manner, or the red, green, blue, and white subpixels can be disposed in a quad type. For example, the red sub pixel, the blue sub pixel, and the green sub pixel can be sequentially disposed along a row direction, or the red sub pixel, the blue sub pixel, the green sub pixel and the white sub pixel can be sequentially disposed along the row direction. However, in the embodiment of the present disclosure, the color type, disposition type, and disposition order of the subpixels are not limiting, and can be configured in various forms according to light-emitting characteristics, device lifespans, and device specifications.

Meanwhile, the subpixels can have different light-emitting areas according to light-emitting characteristics. For example, a subpixel that emits light of a color different from that of a blue subpixel can have a different light-emitting area from that of the blue subpixel. For example, the red subpixel, the blue subpixel, and the green subpixel, or the red subpixel, the blue subpixel, the white subpixel, and the green subpixel can each has a different light-emitting area.

A plurality of light-emitting elements LD can be disposed in each of the plurality of sub-pixels SP. The plurality of light-emitting elements LD can be configured in a manner varying according to the type of the display device 100. For example, when the display device 100 is an inorganic light emitting display device, the light-emitting element can be a light-emitting diode (LED), a micro light-emitting diode (LED), or a mini light-emitting diode (LED). However, example embodiments of the present disclosure are not limited thereto.

A plurality of pixel driving circuits can be disposed in the display panel array PN. The plurality of pixel driving circuits can be configured for driving the light-emitting elements of the plurality of sub-pixels. For example, each of the plurality of pixel driving circuits can function as a driving transistor and a storage capacitor. For example, each of the plurality of pixel driving circuits can supply a control signal, a power, and a driving current to the light-emitting elements of the plurality of sub-pixels to control the light emitting operations of the plurality of light-emitting elements. For example, the pixel driving circuit can include a power line and a signal line for controlling light emission on/off and/or a light emission time of the light-emitting element. For example, the plurality of pixel driving circuits can be a driving driver manufactured using a metal-oxide-silicon field effect transistor (MOSFET) manufacturing process on a semiconductor substrate. However, example embodiments of the present disclosure are not limited thereto. The driving driver can drive the plurality of sub-pixels. For example, each of the plurality of pixel driving circuits can include a micro driver (µDriver). However, example embodiments of the present disclosure are not limited thereto. The micro driver can be implemented in a form of a chip. For example, each of the plurality of pixel driving circuits can include a driver chip. However, example embodiments of the present disclosure are not limited thereto.

The optical control layer can include, for example, a polarization layer POL. The polarizing layer POL prevents a decrease in a contrast ratio (CR) due to external light. In the display device 100 according to the present disclosure, the polarization layer POL that blocks external light incident from the outside can be positioned in a transmission path of light emitted through the display panel 111 in a driving mode in which the LED panel display an image, thereby improving the contrast ratio.

The optical adhesive layer OCA can be composed of at least one or more layers made of at least one or more materials of a OCA (Optical Clear Adhesive), a OCR (Optical Clear Resin), or a PSA (Pressure Sensitive Adhesive).

The optical adhesive layer OCA can have a thickness of, for example, 100 to 300 ㎛. When the optical adhesive layer OCA has a thickness of 100 ㎛ or smaller, the adhesive strength thereof is weakened, so that it is difficult to modularize the cover member CG and the back plate BP into a module. When the optical adhesive layer OCA has a thickness of 300 ㎛ or greater, it can be difficult for the display device 100 to be bent.

The cover member CG protects the display panel 111 from an external impact, and transmits light emitted from the display panel 111 therethrough so that an image displayed from the display panel 111 is visible to the outside. The cover member CG can be referred to as a cover glass or a cover window.

The cover member CG can be made of one of polymethyl methacrylate (PMMA), polycarbonate (PC), cycloolefin polymer (COP), polyethylene terephthalate (PET), PI (polyimide), and PA (polyamide) having impact resistance and light transmittance. However, example embodiments of the present disclosure are not limited thereto.

Referring to FIG. 5, the rear cover 112 can include a metal. Accordingly, the rear cover 112 made of a metal material can accommodate therein the components including the display panel 111 disposed on a rear surface of the cover member CG, and can also protect the components.

When an impact of an external force greater than a predetermined pressure is applied to the display device 100 or the rear cover 112 from the outside, the impact can be reduced by the rear cover 112.

Accordingly, a crack may not be generated in the display panel 111 due to the shock-absorbing function of the rear cover 112, and the display panel 111 can be protected.

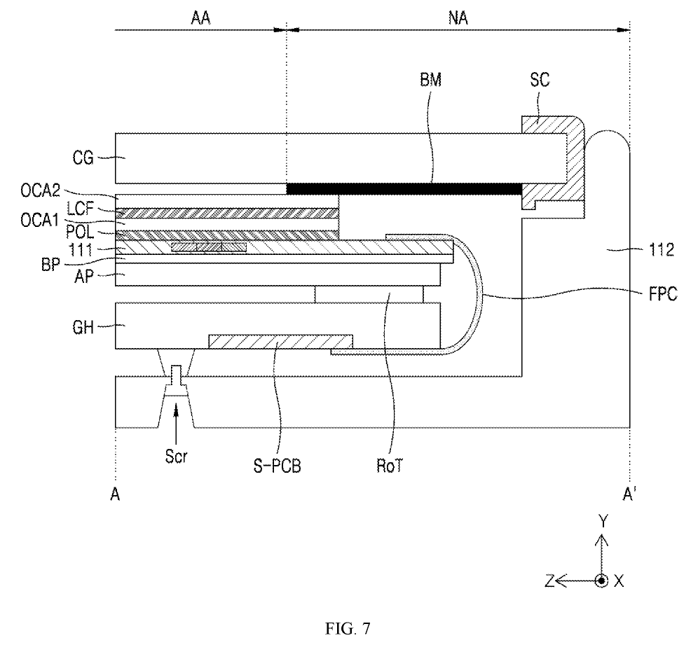

FIG. 6 is a diagram illustrating a cutting line along which a display module according to an example embodiment of the present disclosure is cut, and FIG. 7 is a cross-sectional view illustrating a display module according to an example embodiment of the present disclosure along a cutting line A-A'.

Referring to FIG. 6, the display module 110 according to an example embodiment of the present disclosure can include the display panel 111 mounted on the rear cover 112.

Referring to FIG. 7, in the display device according to an example embodiment of the present disclosure, the cover member CG can be disposed on the display panel 111, and a side cover member SC can be disposed to cover an outer edge of the cover member CG.

The side cover member SC can be disposed to cover an upper surface, a side surface, and a lower surface of each of four outer side portions of the cover member CG.

The display panel 111 can include a display area (Active Area) (hereinafter, referred to as AA) in which a plurality of sub-pixels are disposed and a non-display area (Non-active Area) (hereinafter, referred to as NA) surrounding the display area AA and formed along an outer edge of the display area AA.

The non-display area NA can be an area where no image is displayed and can be defined in an edge portion of the display panel to surround a portion or the entirety of the display area AA. The non-display area NA can be an area adjacent to the display area AA. Further, the non-display area NA can be an area disposed adjacent to the display area AA and configured to surround the display area AA. However, the present disclosure is not limited thereto.

For example, the non-display area NA can include a first non-display area located outside the display area AA in a first direction, a second non-display area located outside the display area AA in a second direction intersecting the first direction, a third non-display area located outside the display area AA in the opposite direction to the first direction, and a fourth non-display area located outside the display area AA in the direction opposite to the second direction.

For another example, a boundary area between the display area AA and the non-display area NA can be bent so that the non-display area NA can be located below the display area. In this case, when the user looks at the display device from the front, there can be little or no non-display area NA visible to the user.

In addition, in the display device, the optical control layer can be disposed on the display panel 111, the optical adhesive layer OCA can be disposed on the optical control layer, and the cover member CG can be disposed on the optical adhesive layer OCA, and the rear cover 112 can be disposed outwardly of the cover member CG so as to be spaced apart from the cover member CG.

The side cover member SC can be disposed between the cover member CG and the rear cover 112 so as to cover an upper surface, a side surface, and a lower surface of each of four outer side portions of the cover member CG.

The side cover member SC can extend along the upper surface, the side surface, and the lower surface of each of the four outer side portions of the cover member CG, and can cover the upper surface, the side surface, and the lower surface of each of the four outer side portions of the cover member CG.

In addition, in the display device, the back plate BP can be disposed under the display panel 111, the metal plate (aluminum plate) AP can be disposed under the back plate BP, an adhesive tape (Resin or Tape) RoT can be disposed under the metal plate AP, a guide holder GH can be disposed under the adhesive tape RoT, and the rear cover 112 can be disposed under the guide holder GH. The guide holder GH can be coupled and fixed to the rear cover 112 through a fastening means such as a screw Scr.

The guide holder GH can contain a source PCB therein, and the source PCB can be electrically connected to the display panel 111 through the flexible printed circuit board FPC.

In addition, in the display device, the black matrix BM can be disposed on the optical adhesive layer OCA, and the cover member CG can be disposed on the black matrix BM.

The black matrix BM can be made of a material with high optical density (OD). Hence, the black matrix BM can absorb or block light.

The black matrix BM can have a plurality of holes defined therein. Black pigments can fill the plurality of holes.

The black matrix BM can be disposed on top of the display panel 111 and in a portion of the non-display area NA between the display area AA and the rear cover 112 located at the outermost position of the non-display area NA. For example, the black matrix BM can be disposed between a second optical adhesive OCA2 and the cover member CG in a vertical direction.

The black matrix BM can include a black pigment (Black Ink or Black Resin), and can be formed such that a concentration of the black pigment can change in a gradation manner, using a separate manufacturing process. The black matrix BM can be disposed between the second optical adhesive layer OCA2 and the cover member CG in the vertical direction. However, a position of the black matrix BM is not limited thereto. For example, the black matrix BM can be formed on the cover member CG in a printed manner such that the concentration of the black pigment can change in a gradation manner during a manufacturing process of the display module 110. In one example, the concentration of the black pigment of the black matrix BM can change in the gradation manner such that the concentration gradually increases as the black matrix BM extends from the display area AA toward the rear cover 112. The black matrix BM can prevent light emitted from the plurality of sub-pixels from being emitted from the non-display area NA.

A density or concentration of the black pigments in the black matrix BM can increase as the black matrix BM extends from the display area AA to the rear cover 112 in the non-display area NA. That is, the density of the black pigments in the black matrix BM can be lower in the display area AA, and the density of the black pigments in the black matrix BM can be higher in the rear cover 112.

In addition, in the display module 110, the optical control layer can be disposed on the display panel 111, a first optical adhesive layer OCA1 can be disposed on the optical control layer, and a light control film LCF can be disposed on the first optical adhesive layer OCA1.

In addition, in the display module 110, the second optical adhesive layer OCA2 can be disposed on the light control film LCF, the black matrix BM can be disposed on the second optical adhesive layer OCA2, and the cover member CG can be disposed on the black matrix BM.

The rear cover 112 can be disposed under the guide holder GH. The rear cover 112 can have a flat bottom in the display area AA and the non-display area NA, can extend upwardly from the bottom at an end of the non-display area NA, and can have an upper end spaced apart from an outer side edge of the cover member CG by a predetermined spacing.

The rear cover 112 can have a stepped portion on which the outer side edge of the cover member CG is seated. Accordingly, the outer portion of the cover member CG and the side cover member SC coupled to the side outer edge of the cover member CG can be seated on the stepped portion of the rear cover 112.

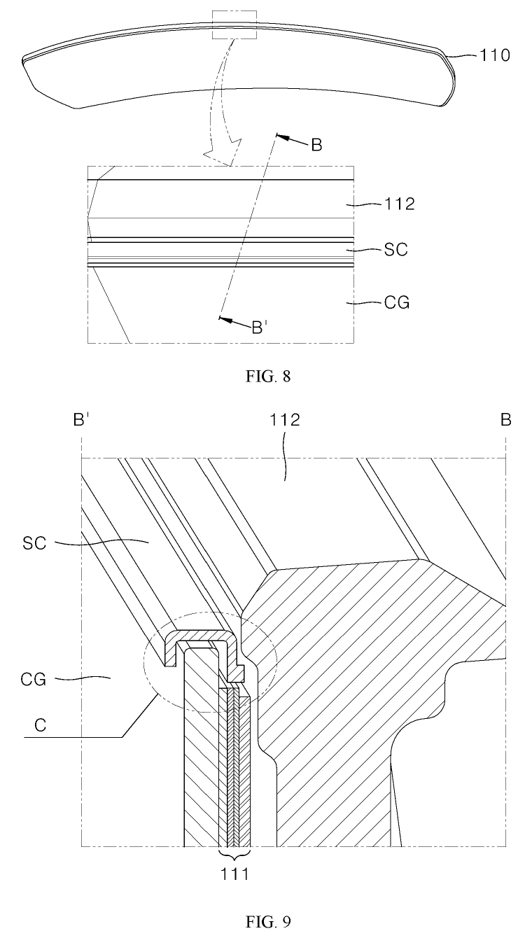

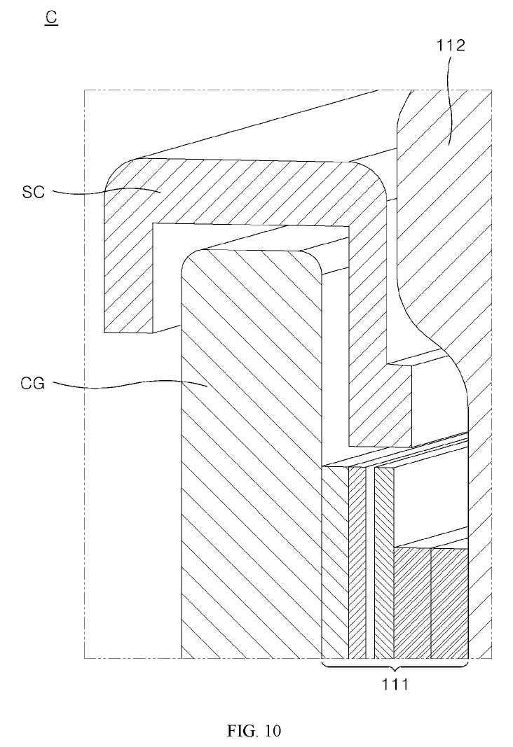

FIG. 8 is a diagram illustrating a detailed configuration example of a display module according to an example embodiment of the present disclosure. FIG. 9 is a cross-sectional view of a display module taken along a line B-B' of FIG. 8 according to an example embodiment of the present disclosure. FIG. 10 is a detailed configuration diagram illustrating a portion C of FIG. 9 in a display module according to an example embodiment of the present disclosure.

Referring to FIG. 8, the display module 110 according to an example embodiment of the present disclosure can have a structure in which the rear cover 112 is disposed at the outermost area of the display module, and the side cover member SC is disposed between the rear cover 112 and the cover member CG.

Referring to FIG. 9, the side cover member SC according to an example embodiment of the present disclosure is inserted into between the outermost portion of the rear cover 112 and the cover member CG such that the outer side edge of the cover member CG is inserted into and is surrounded with the side cover member SC. The side cover member SC is fixedly combined with the cover member CG in a form that is inserted and fitted into the four outer side portions of the cover member CG.

Referring to FIGS. 9 and 10, the display panel 111 can be disposed inwardly of the side cover member SC while being disposed between the rear cover 112 and the cover member CG.

The side cover member SC has a 'U'-shaped cross section, and has a structure in which the outer side edge of the cover member CG is inserted into an space defined by the U-shaped structure.

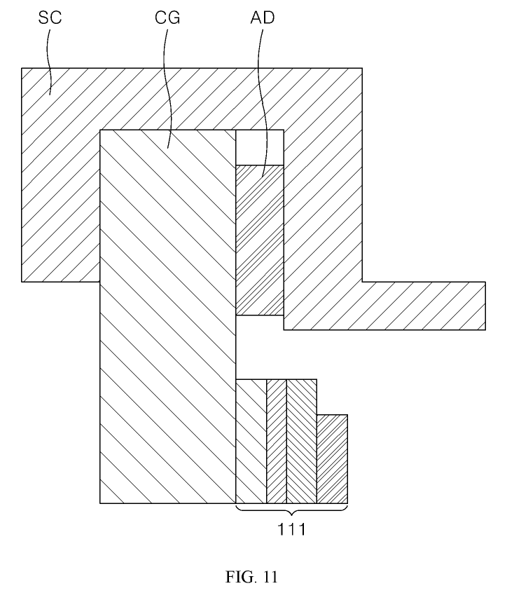

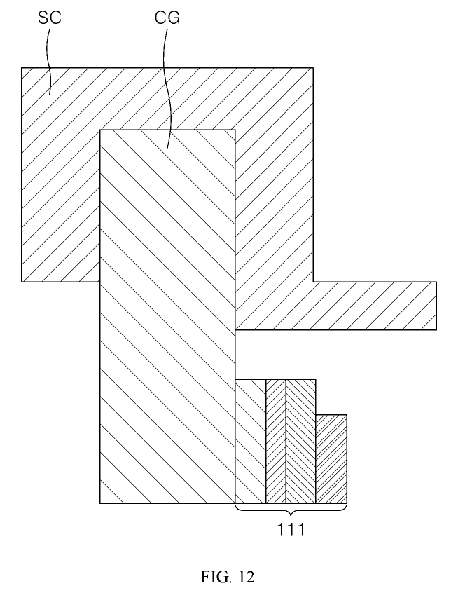

FIG. 11 is a diagram illustrating a coupling state between a side cover member and a cover member according to a first example embodiment of the present disclosure. FIG. 12 is a diagram illustrating a coupling state between a side cover member and a cover member according to a second example embodiment of the present disclosure.

Referring to FIG. 11, the side cover member SC according to the first example embodiment of the present disclosure can be coupled and fixed to the cover member CG through an adhesive AD.

In this case, the side cover member SC has a U shape in the cross-sectional view, and an inner wall defining the 'U' shape and an outer side surface of the cover member CG can be adhered to each other through the adhesive AD.

The side cover member SC can be formed in a molding or metal manner.

The side cover member SC can be made of a plastic material including at least one of polycarbonate (PC), polyimide (PI), polyethylenenaphthalate (PEN), and polyethylene terephthalate (PET).

The side cover member SC can include a metal material, for example, a metal material such as aluminum (Al), stainless steel (SUS), or the like.

The adhesive AD can bond the side cover member SC and the cover member CG to each other in a tape or glue manner.

The adhesive AD can include a foam member. The rear cover 112 and the cover member CG can be adhered to each other through a foam member. The foam member can be formed in a form including a foam tape or a foam pad and can include a tape having a shock absorbing function or a double-sided tape having conductivity. For example, the double-sided tape can include a conductive layer between an upper adhesive layer and a lower adhesive layer, and each of the lower and upper adhesive layers can also include a conductive material.

Referring to FIG. 12, the side cover member SC according to the second example embodiment of the present disclosure can be coupled and fixed to the cover member CG such that the four outer side portions of the cover member CG is closely-fitted into the U-shaped side cover member.

In this regard, the side cover member SC can include rubber or silicon having a flexible material.

The cover member CG can be made of one of poly methyl methacrylate (PMMA), poly carbonate (PC), cycloolefin polymer (COP), polyethylene terephthalate (PET), polyimide (PI), and polyaramid (PA), which have impact resistance and light transmittance. example embodiments of the present disclosure are not limited thereto.

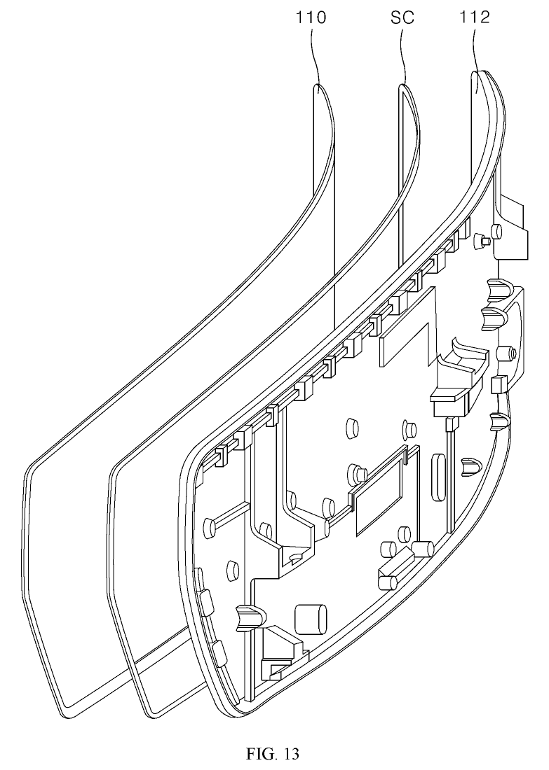

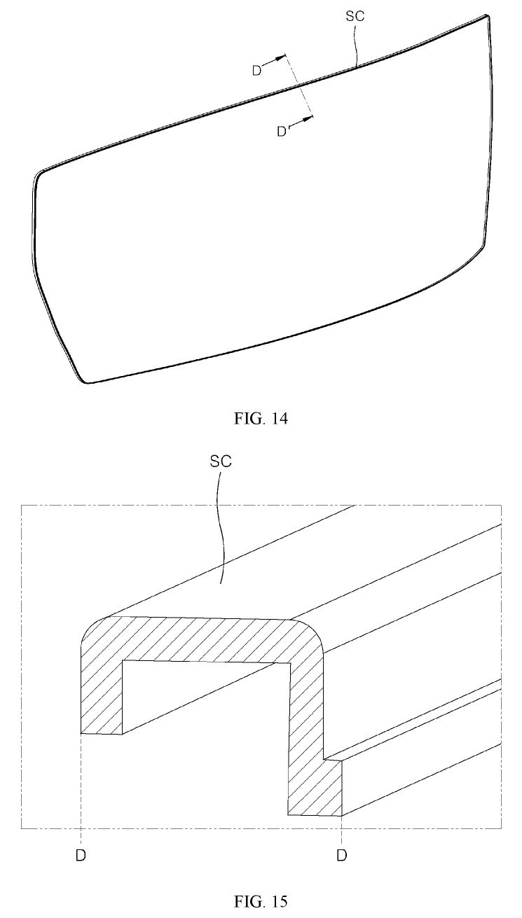

FIG. 13 is a diagram schematically illustrating a configuration example of a display module to which a side cover member is applied according to an example embodiment of the present disclosure. FIG. 14 is a diagram schematically illustrating an outer appearance of a side cover member according to an example embodiment of the present disclosure. FIG. 15 is a cross-sectional view illustrating a cross-section taken along a line D-D' of FIG. 14 of a side cover member according to an example embodiment of the present disclosure.

Referring to FIGS. 13 to 15, the side cover member SC according to an example embodiment of the present disclosure can be disposed between the display module 110 and the rear cover 112.

The side cover member SC can have an opening defined by the U-shaped structure. The opening has a rectangular shape corresponding to that of the outer edge portion of the cover member CG. The opening can have a width slightly smaller or substantially equal to the width of the outer edge portion of the cover member CG such that the outer edge portion of the cover member is closely fitted into the opening of the side the cover member.

The side cover member SC can be formed to have the U-shaped cross-section in a view cut along the line D-D' of FIG. 14.

The side cover member SC can be coupled and fixed to the cover member CG such that the four outer side portions of the cover member CG is closely-fitted into the U-shaped side cover member SC.

In one example, the display device 100 according to an example embodiment of the present disclosure can further include a gate driver, a data driver, and a timing controller,.

The display panel 111 according to an example embodiment of the present disclosure can include a display area where at least one sub-pixel is disposed and a non-display area surrounding the display area.

The display panel 111 according to an example embodiment of the present disclosure can be connected to a plurality of gate lines and data lines. A plurality of sub-pixels SP can be arranged in a matrix form in the display panel 111.

The gate driver can drive the plurality of gate lines. That is, the gate driver can supply a gate signal (scan signal) to the plurality of gate lines.

The gate driver GD can be formed together with the pixel array in the circuit layer of the display panel 111.

The gate driver GD can be arranged on the non-display area NA of the display panel 111, or at least a part thereof can be arranged within the display area AA where the input image is reproduced.

The gate driver GD can be arranged on one side of the left and right non-display areas NA of the display panel 111 and supply gate signals to the gate lines GL in a single feeding manner, without being limited thereto. For example, the gate driver GD can be arranged in the non-display areas NA on both sides of the display panel 111 with the display area AA of the display panel 111 interposed therebetween, and can supply gate pulses on both sides of the gate lines GL in a double feeding manner. The gate driver GD can output pulses of gate signals (hereinafter, "gate pulses") in sequence to the gate lines under the control of the timing controller. The gate driver GD can shift the gate pulses by using a shift register to sequentially supply the resulting signals to the gate lines GL. The gate driver GD can include, but not limited to, one or more shift registers that output pulses of gate signals. The gate signals can include scan pulses and EM pulses of the emission signal.

The data driver can supply data voltage to the plurality of data lines.

The timing controller can control the gate driver and the data driver.

The timing controller can start scanning according to the timing implemented in each frame, convert the input image data input from the outside into the data signal format used by the data driver DD, supply the converted image data to the data driver DD, and control the data driving at an appropriate time according to the scanning.

The timing controller can convert the three primary color pixel data RGB input from the host system HS into four color sub-color data RGBW by adding white data and transfer the same to the data driver DD.

The timing controller can be configured to be coupled with various processors, for example, a microprocessor, a mobile processor, an application processor, etc. in accordance with a device mounted therein.

The timing controller can be implemented in a separate component from the data driver DD, or integrated with the data driver DD, so that the timing controller and the data driver DD can be implemented in a single integrated circuit.

The timing controller can be mounted on a printed circuit board, a flexible printed circuit, or the like, and can be electrically connected to the data driver DD and the gate driver GD through the printed circuit board, the flexible printed circuit, and/or the like.

The timing controller can transmit signals to, and receive signals from, the data driver DD via one or more predetermined interfaces. For example, such interfaces can include a low voltage differential signaling (LVDS) interface, an embedded clock point-point interface (EPI), a serial peripheral interface (SPI), and the like. However, the present disclosure are not limited thereto.

The display device 100 can further include, in addition to the above-described components, a power management circuit that applies power to drive the display panel, a camera for photographing the external environment to the vehicle, and a black box that can store image data captured by the camera.

The display panel 111 according to an example embodiment of the present disclosure can display an image based on the scan signal transmitted thereto from the gate driver through the plurality of gate lines and the data voltage transmitted thereto from the data driver through the plurality of data lines.

When the display module is embodied as the liquid crystal display module, the display panel 111 according to an example embodiment of the present disclosure can include a liquid crystal layer formed between two substrates and can operate in a known mode such as a TN (Twisted Nematic) mode, a VA (Vertical Alignment) mode, a IPS (In Plane Switching) mode, and a FFS (Fringe Field Switching) mode. On the other hand, when the display module is embodied as the organic light-emitting display module, the display panel 111 according to an example embodiment of the present disclosure can operate in a top emission scheme, a bottom emission scheme, or a dual emission scheme.

The display panel 111 according to an example embodiment of the present disclosure can have the plurality of sub-pixels arranged in a matrix form. The sub-pixels can include sub-pixels emitting light of different colors, for example, a white sub-pixel, a red sub-pixel, a green sub-pixel, and a blue sub-pixel. An area of each sub-pixel can be defined by the data lines and the gate lines.

One sub-pixel can include a thin-film transistor TFT formed in an area where one data line and one gate line intersect each other, a light-emitting element such as an organic light-emitting diode that charges the data voltage, and a storage capacitor that is electrically connected to the light-emitting element to maintain the voltage thereof.

An active layer of the thin-film transistor TFT can be formed of a semiconductor material such as an oxide semiconductor, amorphous silicon, or polysilicon, but is not limited thereto.

The oxide semiconductor material can have an excellent effect of preventing or minimizing a leakage current and relatively inexpensive manufacturing cost. The oxide semiconductor can be made of a metal oxide such as zinc (Zn), indium (In), gallium (Ga), tin (Sn), and titanium (Ti) or a combination of a metal such as zinc (Zn), indium (In), gallium (Ga), tin (Sn), or titanium (Ti) and its oxide. Specifically, the oxide semiconductor can include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), indium zinc oxide (IZO), indium gallium tin oxide (IGTO), and indium gallium oxide (IGO), but is not limited thereto.

The polycrystalline semiconductor material has a fast movement speed of carriers such as electrons and holes and thus has high mobility, and has low energy power consumption and superior reliability. The polycrystalline semiconductor can be made of polycrystalline silicon (poly-Si), but is not limited thereto.

The amorphous semiconductor material can be made of amorphous silicon (a-Si), but is not limited thereto.

The gate driver can be controlled by the timing controller so as to sequentially output the scan signal to the plurality of gate lines arranged in the display panel 111 according to an example embodiment of the present disclosure, thereby controlling an operation timing of each of the sub-pixels SP.

For example, sequentially outputting the scan signal on a four gate lines basis, such as sequentially outputting the scan signal to four gate lines including the first gate line to the fourth gate line and then sequentially outputting the scan signal four gate lines including the fifth gate line to the eighth gate line can be referred to as 4 phase operation. In other words, sequentially outputting the scan signal based on a N gate lines basis can be referred to as N-phase operation.

In this regard, the gate driver can include one or more gate driving integrated circuits GDIC. Depending on a driving scheme, the gate driver can be located on only one side of the display panel 111 or on each of both opposing sides thereof. Alternatively, the gate driver can be built into the bezel area of the display panel 111 and thus can be implemented in a GIP (Gate In Panel) form.

The data driver receives sub-image data from the timing controller and converts the received sub-image data into analog data voltage. Then, the data driver outputs the data voltage to each data line in accordance with a timing at which the scan signal is applied through the gate line. Thus, each sub-pixel SP connected to the data line displays a light-emission signal with brightness corresponding to the data voltage.

Likewise, the data driver can include one or more source driving integrated circuits SDIC. The source driving integrated circuit SDIC can be connected to a bonding pad of the display panel 111 using a TAB (Tape Automated Bonding) scheme or a COG (Chip On Glass) scheme, or can be disposed directly on the display panel 111.

In some cases, each source driving integrated circuit SDIC can be integrated into the display panel 111. Furthermore, each source driving integrated circuit SDIC can be implemented in a COF (Chip On Film) manner. In this case, each source driving integrated circuit SDIC can be mounted on a circuit film and can be electrically connected to the data line of the display panel 111 through the circuit film.

The timing controller supplies various control signals to the gate driver and the data driver, and controls the operations of the gate driver and the data driver. In other words, the timing controller controls the gate driver to output the scan signal according to a timing implemented in each frame. On the other hand, the timing controller transmits the image data DATA transmitted thereto from the camera or the image data DATA transmitted thereto through the black box to the data driver.

In this regard, the timing controller can receive, from the host system, the image data DATA and various timing signals which includes a vertical synchronization signal Vsync, a horizontal synchronization signal Hsync, a data enable signal DE, a main clock MCLK, etc.

The host system can include one or more of a TV Television system, a set-top box, a navigation system, a personal computer (PC), a home theater system, a mobile device, a wearable device, a camera 160, and a black box 170. In this regard, an example in which the timing controller receives the image data DATA through the camera that can photograph the external environment to the vehicle or the black box that can store therein the image data DATA taken from the camera will be described below.

Accordingly, the timing controller generates a control signal using the various timing signals received from the camera or the black box and transmits the control signal to the gate driver and the data driver.

For example, the timing controller outputs various gate control signals including a gate start pulse GSP, a gate clock GCLK, and a gate output enable signal GOE, etc. to control the gate driver. In this regard, the gate start pulse GSP controls a timing at which one or more gate driving integrated circuits GDIC constituting a gate driving circuit start operating. Furthermore, the gate clock GCLK is a clock signal commonly input to one or more gate driving integrated circuits GDIC, and controls a shift timing of the scan signal. Furthermore, the gate output enable signal GOE can specify timing information of one or more gate driving integrated circuits GDIC.

Furthermore, the timing controller outputs various data control signals including a source start pulse SSP, a source sampling clock SCLK, and a source output enable signal SOE, etc. to control the data driver. In this regard, the source start pulse SSP controls a timing at which one or more source driving integrated circuits SDICs constituting the data driver start sampling data. The source sampling clock SCLK is a clock signal that controls a timing at which the source driving integrated circuit SDIC samples the data. The source output enable signal SOE controls an output timing of the data driver.

This display device 100 can include the power management circuit that supplies various voltages or currents to the display panel 111, the gate driver, the data driver, or controls the various voltages or currents to be supplied thereto. The power management circuit adjusts a direct current input voltage to generate power required to drive the display panel 111, the gate driver, and the data driver.

The display device 100 according to an example embodiment of the present disclosure refers to a display device having flexibility, and can include a bendable display device, a rollable display device that can be rolled, an unbreakable display device that does not break, and a foldable display device that can be folded.

The driver integrated circuit can be implemented as a TFT (thin film transistor) in the non-display area NA. This driver integrated circuit can be referred to as a GIP (gate-in-panel) circuit. The GIP circuit includes a gate driver of a GIP structure, wherein the gate driver is embodied as a bottom gate type thin-film transistor (BG-T), and a source and drain metal film of a bridge line extends so as to connected to a drain electrode of the BG thin-film transistor.

Moreover, some components, such as the data driver IC can be mounted on a separate printed circuit board, or can be coupled to a connection interface (pads/bumps, pins, etc.) disposed in the non-display area NA using a circuit film such as FPCB (flexible printed circuit board), COF (chip-on-film), or TCP (tape-carrier-package). The non-display area NA can be bent along with the connection interface, so that the printed circuit (COF, PCB, etc.) can be disposed on the rear surface (or the back surface) of the display device 100.

The display device 100 according to the present disclosure can include various additional components for generating various signals or driving the pixel PX in the display area. The additional components to drive the pixel can include an inverter circuit, a multiplexer, and an electrostatic discharge circuit. The display device 100 according to the present disclosure can include additional components related to functions other than the function of driving the pixel. For example, the display device 100 according to the present disclosure can include additional components that provide a touch sensing function, a user authentication function such as fingerprint recognition, a multi-level pressure sensing function, and a tactile feedback function. The above-mentioned additional components can be disposed in an external circuit connected to the non-display area NA and/or the connection interface.

According to the present disclosure, several portions of the display device 100 can be bent along a bendable line. The bendable line can extend transversely, longitudinally, or diagonally. Accordingly, the display device 100 according to an example embodiment of the present disclosure can be bent in a combination of the transverse, longitudinal and diagonal directions based on a required design.

According to the present disclosure, one or more corner edges of the display device 100 can be bent along the bendable line so as to be away from a central portion. The bendable line can be disposed closer to the edge of the display device 100, but can extend across the central portion, or can extend diagonally from one or more corners of the display device 100. This structure can enable the display device 100 to be embodied as a foldable display device or a display device in which an image is displayed from each of both folded surfaces facing each other.

Since one or more portions of the display device 100 can be bent, the display device 100 according to the present disclosure can be divided into a substantially flat area and a curved area. One portion of the display device 100 can be referred to as a substantially flat area. One portion of the display device 100 can be bent at a predetermined angle, and this portion can be referred to as a bent area or a curvature area. The curvature area includes a bent section that is actually bent at a predetermined curvature radius.

The term “substantially flat” means that the substantially flat area includes a portion which is not perfectly flat. For example, a concave central portion and a convex central portion can belong to the substantially flat area in some example embodiments. One or more bent sections can be present next to the concave central portion or the convex central portion, and are bent inwardly or outwardly at an angle relative to a bending axis along the bendable line. The curvature radius of the curvature area is smaller than that of the flat area. In other words, the term "substantially flat area" means a portion with a smaller curvature than that of a portion adjacent thereto.

Depending on a position of the bendable line, a portion on one side of the bendable line is positioned toward the center of the display device 100, while a portion on the other side of the bendable line is positioned toward the edge of the display device 100. A portion positioned toward the center of the display device 100 can be referred to as a central portion, and a portion positioned toward the edge of the display device 100 can be referred to as an edge portion. The central portion of the display device 100 can be substantially flat, and the edge portion can be a bent section. However, this is not always true. The substantially flat area can also be disposed in the edge portion. Further, in some shapes of the display device 100, the bent section can be disposed between two substantially flat areas.

When the non-display area NA is bent, the non-display area NA can be invisible or minimally visible to a viewer in front of the display device 100. A portion of the non-display area NA visible to the view in front of the display device 100 can be screened with a bezel. The bezel can be formed as a stand-alone structure, or as a housing or another suitable element. A portion of the non-display area NA visible to the view in front of the display device 100 can be hidden under an opaque mask layer such as a black ink layer made of black ink (e.g., a polymer filled with carbon black). Such an opaque mask layer can be disposed on various layers (e.g., a touch sensor layer, a polarization layer, a cover layer, and the like) included in the display device 100.

In some example embodiments, the bent section of the display device 100 can include a display area capable of displaying an image. That is, the bendable line can be disposed in the display area so that at least some of pixels of the display area are included in the bent section.

According to an example embodiment of the present disclosure, the display device in which even when the cover member and the side portion of the display module are exposed to the outside, the outer side portion of the cover member is covered with the side cover member so that the light leakage phenomenon does not occur can be realized.

In addition, according to an example embodiment of the present disclosure, there is provided the display device in which the cover member is disposed on top of the display panel in which a plurality of sub-pixels are disposed, and the side cover member is constructed to cover the upper surface, the side surface, and the lower surface of each of the four outer side portions of the cover member.

Although some example embodiments of the present disclosure have been described above with reference to the accompanying drawings, the present disclosure may not be limited to some example embodiments and can be implemented in various different forms. Those of ordinary skill in the technical field to which the present disclosure belongs will be able to appreciate that the present disclosure can be implemented in other specific forms without changing the technical idea or essential features of the present disclosure. Therefore, it should be understood that some example embodiments as described above are not restrictive but illustrative in all respects.

What is claimed is:

1. A display device comprising:
a display panel including a plurality of sub-pixels;
a cover member disposed on the display panel, and including four outer side portions; and
a side cover member constructed to surround at least one of the four outer side portions of the cover member,
wherein the side cover member is constructed to cover an upper surface, a side surface, and a lower surface of each of the four outer side portions of the cover member.

2. The display device of claim 1, wherein the side cover member has a U-shaped cross section, and the at least one of the four outer side portions of the cover member is inserted into a space defined by the U-shaped side cover member.

3. The display device of claim 1, wherein the display device further comprises:
an optical control layer disposed on the display panel;
an optical adhesive layer disposed on the optical control layer;
the cover member disposed on the optical adhesive layer; and
a rear cover spaced from the four outer side portions of the cover member.

4. The display device of claim 3, wherein the optical adhesive layer includes a first optical adhesive layer and a second optical adhesive layer, and
wherein a light control film is disposed between the first optical adhesive layer and the second optical adhesive layer.

5. The display device of claim 3, wherein the side cover member is disposed between the cover member and the rear cover, and covers the upper surface, the side surface, and the lower surface of each of the four outer side portions of the cover member.

6. The display device of claim 4, wherein the side cover member extends on along the upper surface, the side surface, and the lower surface of each of the four outer side portions of the cover member, and
wherein the side cover member overlaps the upper surface, the side surface, and the lower surface of each of the four outer side portions of the cover member.

7. The display device of claim 3, wherein the side cover member is coupled and fixed to the cover member through an adhesive.

8. The display device of claim 3, wherein the side cover member is fixedly combined with the cover member by inserting and fitting the four outer side portions of the cover member into the side cover member.

9. The display device of claim 3, wherein the side cover member is inserted between an outermost portion of the rear cover and the cover member, and the four outer side portions of the cover member are surrounded by the side cover member.

10. The display device of claim 3, wherein the display panel is disposed on a dashboard of a vehicle, and includes a display area in which the plurality of sub-pixels are disposed and a non-display area adjacent to the display area.

11. The display device of claim 10, wherein the rear cover has a flat bottom portion in the display area and the non-display area,
wherein a side portion of the rear cover extends upwardly from the flat bottom portion of the rear cover at an end of the non-display area, and
wherein the side portion of the rear cover has an upper end spaced apart from the four outer side portions of the cover member by a predetermined spacing.

12. The display device of claim 3, wherein the display device further comprises:
a back plate disposed under the display panel;
a metal plate disposed under the back plate;
an adhesive tape disposed under the metal plate; and
a guide holder disposed under the adhesive tape,
wherein a bottom portion of the rear cover is disposed under the guide holder, and
wherein the guide holder is coupled to and fixed to the rear cover through a fastener.

13. The display device of claim 12, wherein a source printed circuit board (PCB) is disposed in the guide holder, and
wherein the source PCB is electrically connected to the display panel through a flexible PCB.

14. The display device of claim 13, wherein the flexible PCB extends from a rear surface of the guide holder to a front surface of the display panel.

15. The display device of claim 3, wherein a black matrix is disposed on the optical adhesive layer, and
wherein the cover member is disposed on the black matrix.

16. The display device of claim 15, wherein the black matrix has a plurality of holes defined therein, and
wherein black pigments fill the plurality of holes.

17. A display device comprising:
a display panel configured to display an image;
a cover member disposed on the display panel and including a plurality of outer side portions; and
a side cover member disposed to surround at least one of the plurality of outer side portions of the cover member,
wherein the side cover member covers at least three different surfaces of each of the plurality of outer side portions of the cover member, and
wherein the at least one of the plurality of outer side portions of the cover member is inserted into a space created by a shape of the side cover member.

18. The display device of claim 17, wherein the side cover member is coupled and fixed to the cover member through an adhesive.

19. The display device of claim 17, wherein the display panel is disposed in a vehicle and includes a display area and a non-display area surrounding the display area.
